(19) United States
(12) Patent Application Publication
(10) Pub. No.: US 2024/0125713 A1
(43) Pub. Date: Apr. 18, 2024

(54) Defect Inspection System and Method

(71) Applicant: Taiwan Semiconductor Manufacturing Co., Ltd., Hsinchu (TW)

(72) Inventors: Hao Chun Yang, New Taipei City (TW); Ming-Da Cheng, Taoyuan (TW); Pei-Wei Lee, Kaohsiung City (TW); Mirng-Ji Lii, Sinpu Township (TW)

(21) Appl. No.: 18/152,409

(22) Filed: Jan. 10, 2023

Related U.S. Application Data
(60) Provisional application No. 63/379,801, filed on Oct. 17, 2022.

(51) Int. Cl. G01N 21/95; G01N 21/59

(52) U.S. Cl. CPC G01N 21/9505; G01N 21/59; G01N 2201/06113; G01N 2201/0636

(57) ABSTRACT

A method includes directing light at a first side of a semiconductor structure; detecting a first light intensity at a second side of the semiconductor structure, wherein the first light intensity corresponds to the light that penetrated the semiconductor structure from the first side to the second side; and comparing the first light intensity to a second light intensity, wherein the second light intensity corresponds to an expected intensity of light.

### PRIORITY CLAIM AND CROSS-REFERENCE

This application claims the benefit of U.S. Provisional Application No. 63/379,801, filed on Oct. 17, 2022, entitled “Defect Inspection System and Method,” which application is incorporated herein by reference.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs. In the course of integrated circuit evolution, functional density (such as the number of interconnected devices per chip area) has generally increased while geometry size (such as the smallest component that can be created using a fabrication process) has decreased. This scaling down process generally provides benefits by increasing production efficiency and lowering associated costs. As a part of the IC fabrication process, wafers may be inspected for potential defects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a semiconductor processing system including a transmission inspection system, in accordance with some embodiments.

FIG. 2 illustrates a top view of a semiconductor wafer, in accordance with some embodiments.

FIGS. 3, 4, and 5 are cross-sectional views of intermediate stages in the manufacturing of a semiconductor device, in accordance with some embodiments.

FIG. 6 illustrates an example of a FinFET in a three-dimensional view, in accordance with some embodiments.

FIGS. 7 and 8 are cross-sectional views of a semiconductor device, in accordance with some embodiments.

FIGS. 9 and 10 are schematic illustrations of a transmission inspection system, in accordance with some embodiments.

FIGS. 11A and 11B are illustrations of example detected light measurements, in accordance with some embodiments.

FIG. 12 is schematic illustration of a transmission inspection system, in accordance with some embodiments.

FIG. 13 is schematic illustration of a transmission inspection system including a stage, in accordance with some embodiments.

FIG. 14 is schematic illustration of a transmission inspection system including a stage, in accordance with some embodiments.

FIG. 15 is schematic illustration of a transmission inspection system including a stage, in accordance with some embodiments.

FIG. 16 is schematic illustration of a transmission inspection system, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a defect inspection system utilizes the transmission of light through a semiconductor structure to identify defects. For example, light may be directed at one side of the semiconductor structure, and any light transmitted entirely through the semiconductor structure may be detected or measured by a detector. The presence of a defect may block or absorb light within the semiconductor structure, resulting in a reduction of detected or measured light at the detector. In this manner, measuring the intensity of transmitted light and comparing the measured intensity to an expected intensity may reveal the presence of defects in regions where the measured intensity is lower than expected. The technique and system as described herein can increase the signal-to-noise ratio of defect detection, allow for the detection of defects within a structure, decrease defect inspection time, and increase throughput, which can reduce processing costs, in some cases.

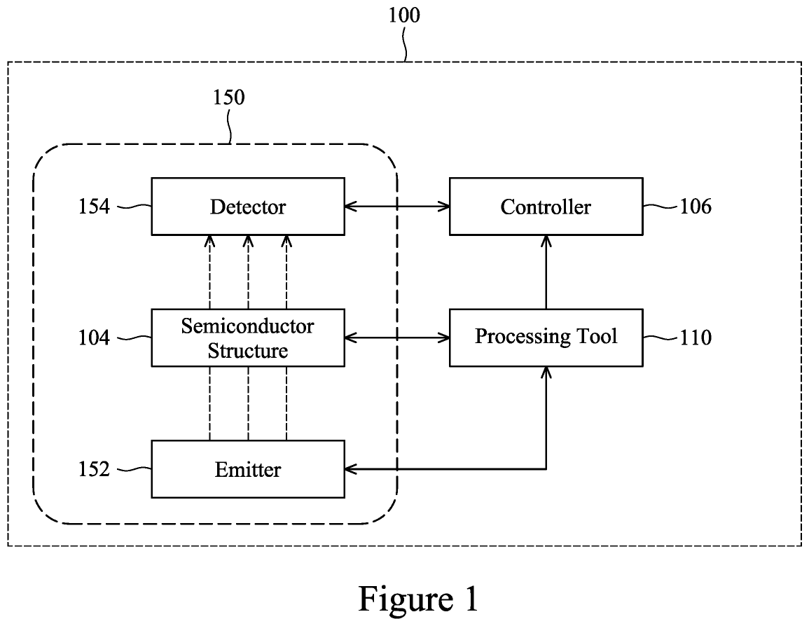

FIG. 1 is a block diagram of a semiconductor processing system 100, in accordance with some embodiments. The semiconductor processing system 100 includes a transmission inspection system 150, a controller 106, and a processing tool 110. The components of the semiconductor processing system 100 work together to perform a semiconductor process on a semiconductor structure 104 (e.g., a semiconductor wafer or the like, described in greater detail below). The semiconductor processing system 100 utilizes the transmission inspection system 150 to inspect and/or analyze the semiconductor structure 104 for defects. The transmission inspection system 150 includes a emitter 152 and a detector 154, in some embodiments. During inspection, the emitter 152 directs light (or, in some embodiments, electrons) toward the semiconductor structure 104, and the detector 154 detects light that has transmitted through the semiconductor structure 104. In some embodiments, the controller 106 receives detection data from the detector 154, and may analyze, compare, display, or otherwise process the detection data for defect identification. In some embodiments, the control 106 controls the operation of the transmission inspection system 150.

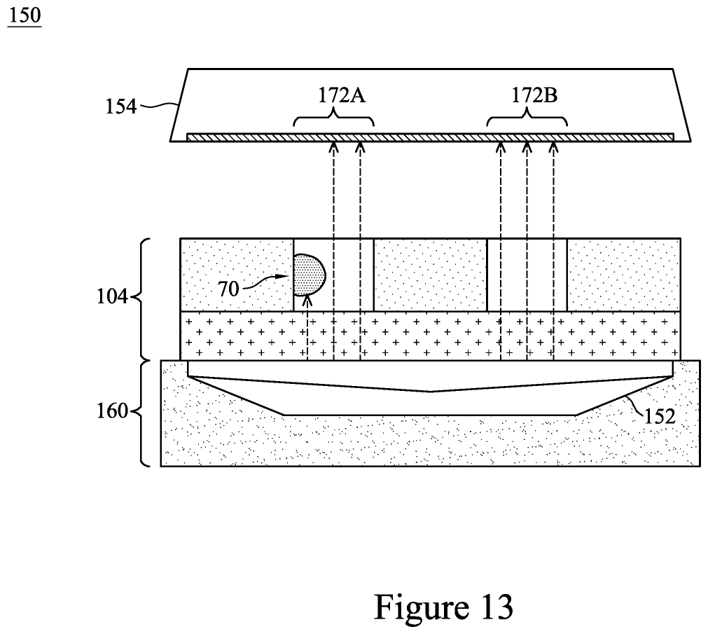

In some embodiments, the emitter 152 of the transmission inspection system 150 illuminates the semiconductor structure 150 and emits the light that may be transmitted through the semiconductor structure 150 and detected by the detector 154. The emitter 152 may illuminate the entire semiconductor structure 104 or may illuminate a region of the semiconductor structure 104. The emitter 152 may include a source of electromagnetic radiation (e.g., light) having any suitable wavelength(s) and any suitable power, in some embodiments. For example, the emitter 152 may emit infrared light, visible light, ultraviolet light, X-rays, light pulses, laser light, the like, or a combination thereof. The emitter 152 may provide a single wavelength of light, multiple wavelengths of light, or a range of wavelengths of light (e.g., a spectrum). In some embodiments, the emitter 152 may include a laser, a LED, a lamp (e.g., a light bulb or other incandescent source), a phosphorescent material, a fluorescent material, a chemiluminescent material, or the like. Other emitters having other characteristics are possible. For simplicity, the emitter 152 may be described herein as emitting “light,” but it should be understood that other types of emission are possible and considered within the scope of the present disclosure. For example, in other embodiments, the emitter 152 emits a beam of electrons that may be transmitted through the semiconductor structure 150 and detected by the detector 154. The emitter 152 may include appropriate lenses, mirrors, actuators, electromagnets, the like, or any other appropriate optical, electronic, or mechanical components. In some embodiments, the emitter 152 may be incorporated into a stage 160 (see FIG. 13 for an example embodiment).

The detector 154 of the transmission inspection system 150 is configured to detect or image light from the emitter 152 that is transmitted through the semiconductor structure 104. In some embodiments, the detector 154 and the emitter 152 are positioned on opposite sides of the semiconductor structure 104. The detector 154 may include any suitable light detector configured to detect or measure light intensity. For example, the light detector 154 may include a photodetector, a photodiode, a phototransistor, a camera, a CCD, or the like. In some embodiments, the detector 154 may measure an average or accumulated light intensity from the entire semiconductor structure 104 or from a region of the semiconductor structure 104. In some embodiments, the detector 154 may image the entire semiconductor structure 104 or a region of the semiconductor structure 104. In some embodiments, the detector 154 may send detection data or image data to the controller 106, and the controller 106 (or an associated module) generates a measurement or an image from the received data. In some embodiments, the detector 154 is configured to detect or image electrons from the emitter 152 that are transmitted through the semiconductor structure 104. Other detectors having other characteristics are possible.

The processing tool 110 is configured to perform one or more of a large number of manufacturing processes on the semiconductor structure 104, such as photolithography processes, etching processes, deposition processes (e.g., thin-film deposition processes or the like), planarization processes, doping processes, annealing processes, the like, or other types of processes. For example, the processing tool 110 may include an etcher, an implanter, a deposition system, a photolithography system, or the like. The various processes may be part of a front-end of line (FEOL) process to form devices such as transistors (e.g., Fin Field-Effect Transistors (FinFETs), nanoFETs, or the like) or other active or passive devices, in some embodiments. The various processes may also be part of a back-end of line (BEOL) process to form interconnect structures (e.g., conductive lines, conductive vias, metallization patterns, redistribution layers, or the like), in some embodiments. Other processes or formed features are possible.

In a non-limiting example, the processing tool 110 may be utilized to perform one or more processes in a series of semiconductor processes to form patterned features on a substrate. Accordingly, the semiconductor processes may include forming a target layer over the semiconductor structure 104, depositing a hard mask layer over the target layer, and patterning the hard mask layer to form a patterned hard mask. The semiconductor processes may further include etching the target layer using the patterned hard mask as an etching mask, thereby forming patterned features from the target layer. The patterned features (e.g., semiconductor strips, conductive lines, etc.) may have the pattern of the hard mask. The hard mask may then be then removed, leaving the patterned features. In some cases, the hard mask may be incompletely removed such that hard mask residue is left remaining on the semiconductor structure 104. In some cases, the target layer may be incompletely etched, leaving target layer material remaining in undesirable locations. In some cases, the transmission inspection system 150 described herein may be utilized to detect these or other defects formed during semiconductor processes.

In some embodiments, the controller 106 is configured to control the transmission inspection system 150 and/or the processing tool 110. Accordingly the controller 106 may be communicatively coupled to components of the transmission inspection system 150 and/or the processing tool 110. The controller 106 may also control a stage or holder, in some embodiments. The controller 106 may be configured to receive detection data or image data from the detector 154, and may be further configured to process or analyze the received data, in some embodiments. The controller 106 may be implemented in either hardware or software, and instructions or parameters may be hardcoded within the controller 106 or may be input to the controller 106 through an input device. For example, the controller 106 may be a circuit such as an application-specific integrated circuit (ASIC), a field programmable gate array (FPGA), or the like. The controller 106 may also include a processor operable to execute programming. In some embodiments, the controller 106 comprises one or more programmable computer(s), and the methods described herein are implemented as programming executed by a processor. The controller 106 is illustrated as a single element for illustrative purposes. In some embodiments, the controller 106 comprises multiple elements. The controller 106 may include storage (e.g., volatile or non-volatile memory) for storing detection data and/or images that can be used for defect detection.

After one or more semiconductor processes have been performed on the semiconductor structure 104, it can be beneficial to inspect the semiconductor structure 104 for defects. In some cases, the inspection may be performed using the transmission inspection system 150 described herein. Inspection can help ensure that the processes performed by the processing tool 110 have accomplished their intended purpose. If defects are identified, then further processing of the semiconductor structure 104 may be halted to reduce manufacturing costs, and the processes (e.g., parameters associated with the processes), may be adjusted to reduce the formation of defects in the future. If no defects are identified, then the processes may be assumed to be functioning properly and may not need to be adjusted. In this manner, processing yield, processing efficiency, and/or device reliability may be improved.

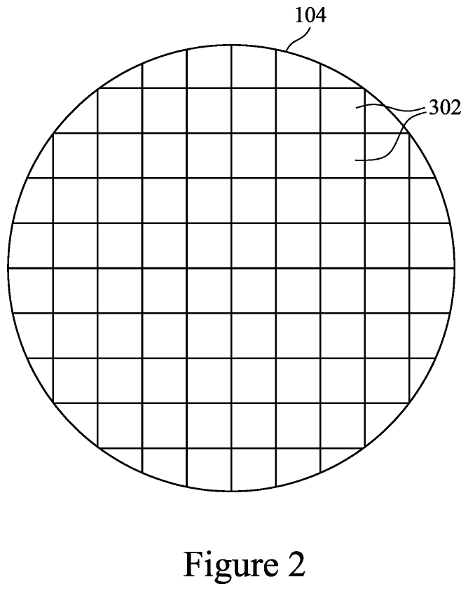

FIG. 2 illustrates a plan view of a semiconductor structure 104, in accordance with some embodiments. The semiconductor structure 104 may be, for example, a semiconductor wafer, an interposer, a panel, a carrier, a die attach film (DAF), a core substrate, or the like, which may include any features or devices formed thereon. The semiconductor structure 104 may be partially or fully processed. The illustration of FIG. 2 shows that the semiconductor structure 104 is divided into a plurality of regions 302. Each region 302 may correspond, for example, to a single device formed on the semiconductor structure 104, a group of adjacent devices formed on the semiconductor structure 104, a portion of a single device formed on the semiconductor structure 104, or the like. The semiconductor structure 104 may include any desired quantity of regions 302, including more or fewer regions 302 than shown in FIG. 2. The regions 302 may be of similar size or may be of different sizes. The regions 302 may be adjacent and/or separated. In some embodiments, each region 302 corresponds to at least one transmittable region 72 of the semiconductor structure 104, described in greater detail below.

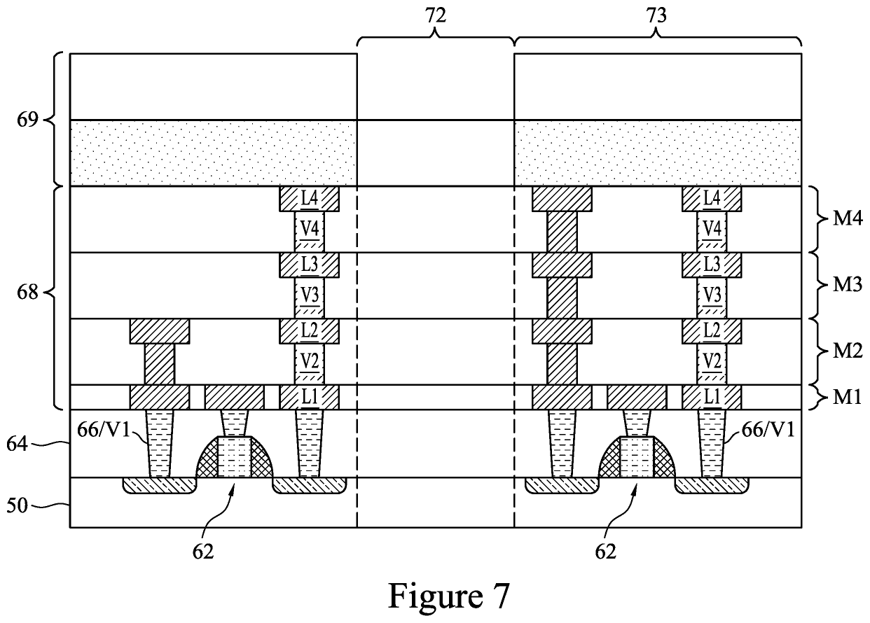

In some embodiments, one or more of the regions 302 may be inspected using the transmission inspection system 150. For example, the emitter 152 may be configured to illuminate one or more of the regions 302, and the detector 154 may be configured to detect light transmitted through the one or more regions 302. In some embodiments, all of the regions 302 of a semiconductor structure 104 are inspected. In other embodiments, only selected regions 302 of a semiconductor structure 302 are inspected. As a non-limiting example, in some embodiments, only regions 302 suspected or identified as having defects may be selected for inspection, with known good regions 302 being omitted from inspection. In some embodiments, each region 302 may comprise one or more transmittable regions 72 (see FIG. 7). Other rationales or techniques are possible.

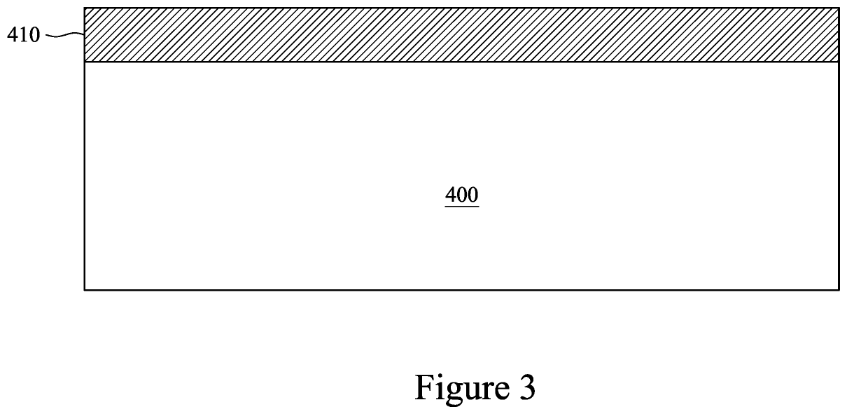

FIGS. 3 through 5 illustrate intermediate stages in an example patterning of a target layer 400 by the semiconductor processing system 100 (see FIG. 1), in accordance with some embodiments. An inspection process may be performed during or after patterning of the target layer 400. The inspection process may be performed using the transmission inspection system 150, in some embodiments.

FIG. 3 illustrates a cross-sectional view of a target layer 400 and a hard mask layer 410 over the target layer 400, in accordance with some embodiments. The target layer 400 represents a layer in which a pattern is to be formed. The target layer 400 may be part of a semiconductor structure 104 or formed on a semiconductor substrate 104. For example, the target layer 400 may be a portion of a semiconductor substrate, in some embodiments. The semiconductor substrate may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), the like, or a combination thereof. Other substrates that may be used include multi-layered substrates, gradient substrates, hybrid orientation substrates, or the like. The semiconductor substrate may comprise active and/or passive devices formed thereon, or the semiconductor substrate may be free of active and/or passive devices. In some cases, the semiconductor substrate may include one or more dielectric layers (e.g., isolation regions, etch stop layers, interlayer dielectric (ILD) layers, inter-metal dielectric (IMD) layers, the like, or a combination thereof), one or more conductive layers (e.g., metal layers, polysilicon layers, metallization patterns, redistribution layers, the like, or a combination thereof), the like, or a combination thereof. A hard mask layer 410 is formed over the target layer 400 and may be formed of a hard mask material. Acceptable hard mask materials include oxides, such as titanium oxide, silicon oxide, the like, or a combination thereof; nitrides, such as titanium nitride, silicon nitride, the like, or a combination thereof; or the like. The material of the hard mask layer 410 may be formed by a suitable deposition process, such as chemical vapor deposition (CVD), atomic layer deposition (ALD), or the like. The target layer 400 and mask layer 410 are illustrative examples, and other materials, techniques, or features are possible.

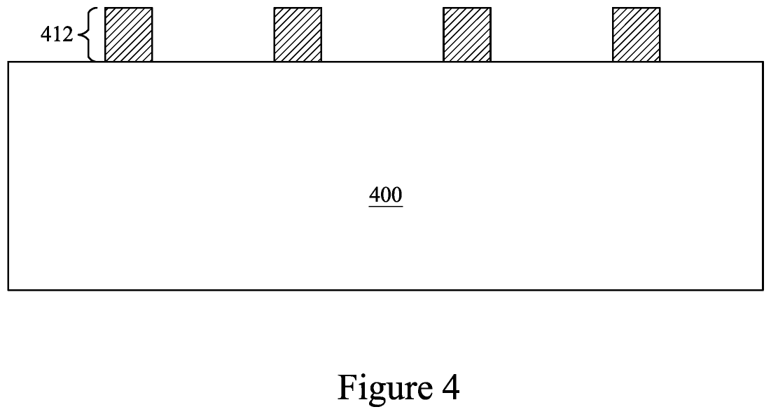

In FIG. 4, the hard mask layer 410 is patterned to form a hard mask 412, in accordance with some embodiments. The hard mask 412 is subsequently used to pattern the target layer 400. As an example of patterning the hard mask layer 410, a photoresist (not illustrated) is formed over the hard mask layer 410. The photoresist can be formed by using a spin-on technique and can be patterned using acceptable photolithography techniques. In some embodiments, the patterned photoresist may be inspected for defects using the transmission inspection system 150. The patterned photoresist is used as an etching mask to etch and pattern the hard mask layer 410, thus forming a patterned hard mask 412. After patterning the hard mask layer 410, the photoresist is removed, such as by an acceptable ashing process. In some embodiments, the patterned hard mask 412 is inspected for defects using the transmission inspection system 150. For example, the transmission inspection system 150 may be able to identify the presence of photoresist residue, in some cases. Further processing may be halted if defects are identified during inspection of the patterned photoresist and/or the patterned hard mask 412, in some cases.

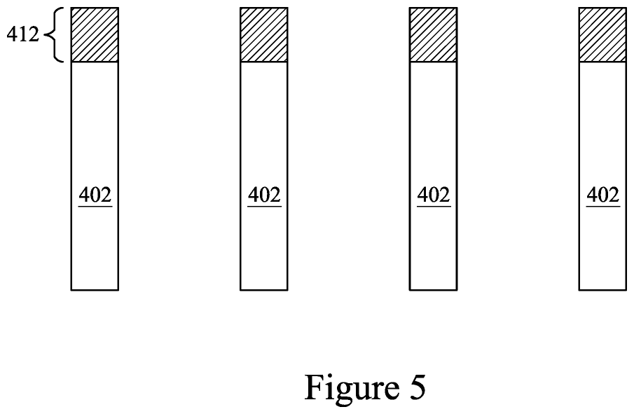

In FIG. 5, the hard mask 412 is used to pattern the target layer 400, thus forming patterned target features 402, in accordance with some embodiments. The target layer 400 may be patterned by any suitable method, such as using a dry or wet etching process, with the hard mask 412 used as an etching mask. In some embodiments, the patterned target features 402 may be inspected for defects using the transmission inspection system 150. Further processing may be halted if defects are identified during inspection of the patterned target features 402, in some cases. In some embodiments, the patterned target features 402 are semiconductor fins extending from a semiconductor substrate. In some embodiments, the patterned target features 402 are nanostructures (e.g., nanowires, nanosheets, etc.) over a semiconductor substrate. In some embodiments, the target layer 400 is a dielectric layer, and transferring the pattern of the hard mask 412 to the target layer 400 forms trenches, recesses, and/or openings in the dielectric layer. In some embodiments, conductive features (e.g., conductive lines and/or vias) may be subsequently formed in the trenches, recesses, and/or openings. In some embodiments, the patterned target features 402 are portions of a conductive layer, such as a conductive layer forming metal gates for transistors. In some embodiments, the hard mask 412 is subsequently removed from the patterned target features 402 using a suitable process such as a planarization process (e.g., a chemical-mechanical planarization (CMP) process), an etching process, or the like. These are examples, and other features, structures, materials, or techniques are possible.

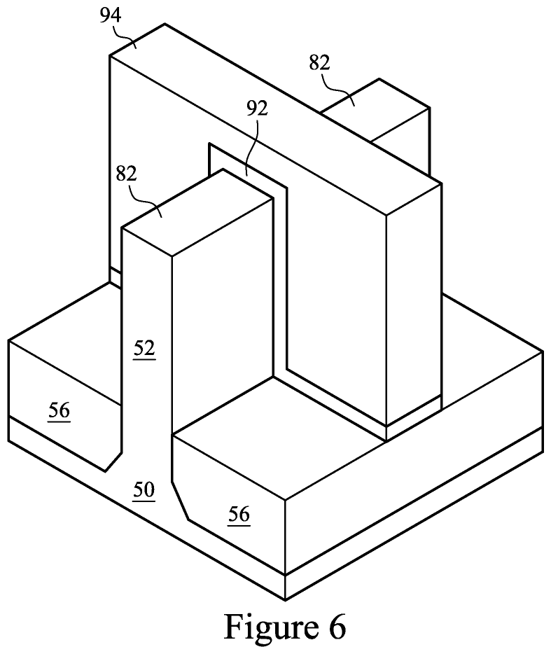

FIG. 6 illustrates a Fin Field-Effect Transistor (FinFET) in a three-dimensional view, in accordance with some embodiments. The FinFET may be formed as part of a semiconductor structure 104, and may be formed using the processing tool 110, in some embodiments. For example, various features of the FinFET may be formed using patterning processes, such as the process described above in FIGS. 3-5. The transmission inspection system 150 may be used to inspect for defects at one or more intermediate stages of manufacturing a FinFET, in some cases. The FinFET comprises a fin 52 on a substrate 50 (e.g., a semiconductor substrate). Isolation regions 56 are disposed over the substrate 50, and the fin 52 protrudes above and from between neighboring isolation regions 56. Although the isolation regions 56 are described/illustrated as being separate from the substrate 50, as used herein the term “substrate” may be used to refer to just the semiconductor substrate or a semiconductor substrate inclusive of the isolation regions 56. Additionally, although the fin 52 is illustrated as a single, continuous material as the substrate 50, the fin 52 and/or the substrate 50 may comprise a single material or a plurality of materials. In this context, the fin 52 refers to the portion extending between the neighboring isolation regions 56. In some embodiments, the fin 52 is formed by similar methods as the patterned target features 402 as described above with respect to FIGS. 3-5.

A gate dielectric layer 92 is along sidewalls and over a top surface of the fin 52, and a gate electrode 94 is over the gate dielectric layer 92. Source/drain regions 82 are disposed in opposite sides of the fin 52 with respect to the gate dielectric layer 92 and gate electrode 94. In some embodiments, the gate electrode 94 is formed by a gate replacement process including the patterning of dummy gates by similar methods as the patterning of the patterned target features 402 as described above with respect to FIGS. 3-5. In some embodiments, the transmission inspection system 150 is used to inspect the pattern of the dummy gates at one or more intermediate stages of manufacturing. This is an example, and other FinFETs or processes for forming FinFETs are possible.

FIG. 7 illustrates a cross-sectional view of a semiconductor device, in accordance with some embodiments. The semiconductor device may be part of a semiconductor structure 104. Various features in FIG. 7 may be formed by patterning processes such as the process described above in FIGS. 3-5, with transmission inspection system 150 defects at one or more intermediate stages of manufacturing. FIG. 7 is a simplified view for illustrative purposes, and some features of the semiconductor device may be omitted for clarity of illustration. Additionally, the semiconductor device shown in FIG. 7 is an illustrative example, and those skilled in the art should appreciate that the embodiments and techniques described herein are applicable to a wide variety of structures, devices, chips, packages, or the like.

FIG. 7 illustrates devices 62 formed over a substrate 50, in accordance with some embodiments. The substrate 50 may be similar to or different from the substrate 50 described previously for FIG. 6. The devices 62 may be formed at an active surface of the substrate 50, in some embodiments. The devices 62 may comprise active devices and/or passive devices. The devices 62 are represented in FIG. 7 as transistors. However, as one of skill in the art will recognize, a wide variety of devices such as transistors, diodes, capacitors, resistors, inductors, or the like may be used to generate the desired structural and functional requirements of the design for the semiconductor device. The devices 62 may be formed using any suitable methods.

One or more inter-layer dielectric (ILD) layer(s) 64 may be formed on the substrate 50 and over the devices 62, in some embodiments. Electrically conductive features, such as contact plugs 66, may be formed within the ILD layer(s) 64 to physically and electrically contact the devices 62. The electrically conductive features in the ILD layer(s) 64 may be formed using any suitable process, such as deposition, damascene (e.g., single damascene, dual damascene, etc.), the like, or a combination thereof. In some embodiments, the patterning of the ILD layer(s) 64 in order to form the electrically conductive features may be performed by similar methods as the patterning of the patterned target features 402 as described above with respect to FIGS. 3-5. In some embodiments, the transmission inspection system 150 may be used to inspect the pattern(s) of the ILD layer(s) 64 at one or more intermediate stages of manufacturing.

An interconnect structure 68 may be formed over the substrate 50, in accordance with some embodiments. The interconnect structure 68 may be formed over the ILD layer(s) 64, and may interconnect the devices 62 to form integrated circuits. The interconnect structure 68 includes multiple metallization layers M1-M4. Although four metallization layers are illustrated in FIG. 7, it should be appreciated that more or fewer metallization layers may be present. Each of the metallization layers M1-M4 includes metallization patterns formed in dielectric layers, which may be inter-metal dielectric (IMD) layers. The metallization patterns may be electrically coupled to the devices 62 of the substrate 50 and may be electrically coupled to underlying and/or overlying metallization patterns or other conductive features. The metallization patterns of the metallization layers M1-M4 may include, respectively, conductive lines L1-L4 and vias V1-V4 formed in one or more IMD layers. The interconnect structure 68 may formed using a suitable process, such as a damascene process (e.g., a single damascene or a dual damascene process) or the like. In some embodiments, the contact plugs 66 are also part of the metallization patterns, such as part of the lowest layer of metal vias V1. In some embodiments, the patterning of the IMD layers in order to form the conductive lines L1-L4 and vias V1-V4 may be performed using similar techniques as the patterning of the patterned target features 402 as described above with respect to FIGS. 3-5. In some embodiments, the transmission inspection system 150 may be used to inspect the pattern of features of the interconnect structure 68 (e.g., the patterns of the IMD layers or the metallization patterns) at one or more intermediate stages of manufacturing. In some embodiments, one or more dielectric layers 69 may be formed over the interconnect structure 68. In some embodiments, conductive features (not shown) may be formed in or on the dielectric layers 69, which may include conductive lines, vias, contact pads, under-bump metallizations (UBMs), other conductive features, or the like. This is an example, and other interconnect structures and formation techniques are possible.

Still referring to FIG. 7, the semiconductor device (e.g., the semiconductor structure 104) may include one or more transmittable regions 72, in accordance with some embodiments. The transmittable regions 72 may be present during and/or after manufacture of the semiconductor device. The transmittable regions 72 are regions of the semiconductor device through which light may be transmitted. The transmittable regions 72 may extend from a first side (e.g., a back side) of the semiconductor device to a second side (e.g., a front side) of the semiconductor device. Accordingly, within a transmittable region 72, light is able to penetrate the full thickness of the semiconductor and emerge from a surface of the semiconductor device. In other words, the transmittable regions 72 may be a region that is transparent or semitransparent to one or more wavelengths of light emitted by the emitter 152, such that light transmitted through the transmittable region 72 is able to be detected by the detector 164. In some cases, a transmittable region 72 may be transparent (or semitransparent) to a first wavelength of light but not a second wavelength of light, depending on the materials present. In some cases, different transmittable regions 72 of a semiconductor device may be transparent (or semitransparent) to different wavelengths of light. In this manner, in some embodiments, the light source 162 and/or the detector 164 may be configured to utilize multiple wavelengths of light.

In some cases, the transmittable regions 72 may be free of structures, features, or layers comprising materials that block or absorb relevant wavelengths of light. The shapes, locations, and number of the transmittable regions 72 of a semiconductor device may depend on the structures, features, or layers of the semiconductor device and the corresponding materials used. In some cases, a transmittable region 72 may comprise an air gap, hollow region, opening, or trench. The opaque region 73 in FIG. 7 indicates an example region in which light within the semiconductor device would be blocked, absorbed, or otherwise prevented from being transmitted completely through the semiconductor device. For example, the opaque region 73 may comprise structures, features, or layers comprising materials that block or absorb relevant wavelengths of light, such as metallic materials.

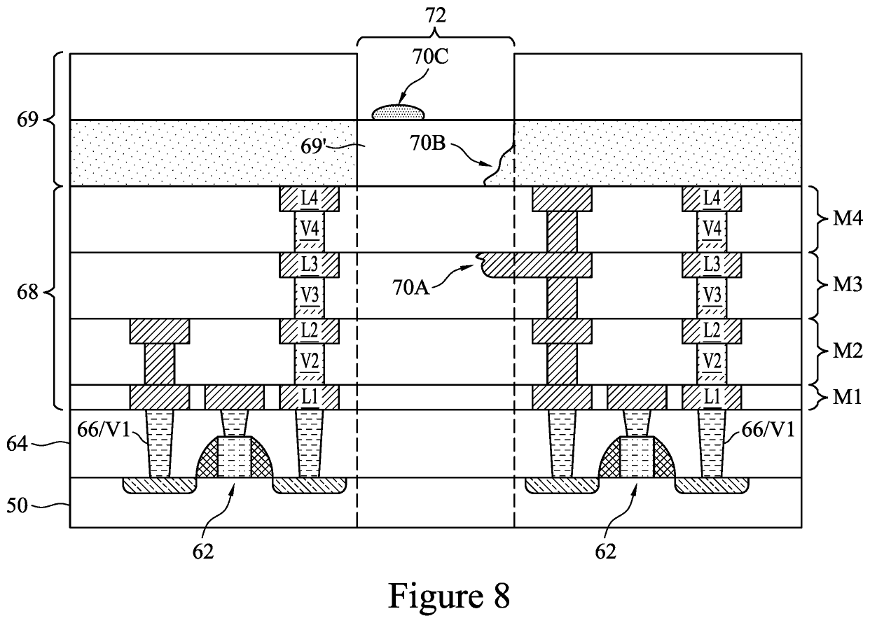

FIG. 8 shows the cross-sectional view of FIG. 7, but includes illustrative examples of defects 70 that may be present in a transmittable region 72, in accordance with some embodiments. The defects 70A-C represent some of the types of defects that may be present within a transmittable region 72. In particular, the defects 70A-C represent defects that may be detected by the transmission inspection system 150. In some cases, the defects 70A-C comprise materials that block or absorb light within the transmittable region 72. In other words, the defects 70A-C may cause more light to be blocked or absorbed within a transmittable region 72 than if the defects 70A-C were not present. This increased blocking/absorption of light can allow the transmission inspection system 150 to detect, identify, image, or categorize the defects 70A-C, described in greater detail below. The defects 70A-C are intended as examples, and other types of defects detectable by the transmission inspection system 150 are possible. The defects 70A-C may be present during an intermediate stage in the manufacture of a semiconductor device and/or may be present after manufacture of a semiconductor device.

The defect 70A represents a defect in which a conductive line (e.g., L3) has been incompletely etched or removed during formation, and a region of conductive material is present in the transmittable region 72. The defect 70A may also be formed, for example, by conductive material penetrating a crack or seam during deposition. The metal material of the defect 70A blocks light within the transmittable region 72, in some cases. The defect 70B represents a defect in which a dielectric layer 69 has been incompletely etched, and material of that dielectric layer 69 remains within the transmittable region 72. In the example of FIG. 8, the defect 70B is covered by a different dielectric material 69′ that is more transparent to light than the defect 70B. Thus, the defect 70B may block or absorb light that would otherwise be transmitted through the dielectric material 69′. The defect 70C represents a defect comprising residue remaining on a surface within the transmittable region 72. In the example of FIG. 8, the defect 70C remains on a top surface of the dielectric material 69′, but the residue of the defect 70C may be on other surfaces, such as sidewall surfaces, underneath under-cut surfaces, or on surfaces within the semiconductor device. The residue may comprise, for example, incompletely removed photoresist, incompletely removed dielectric or conductive material, incompletely removed etching or deposition byproducts, contaminants, the like, or a combination thereof. The residue of the defect 70C may block or absorb light from the emitter 152 that would otherwise reach the detector 154. The defects 70A-C are examples, and other defects 70A-C detectable by the transmission inspection system 150 are possible.

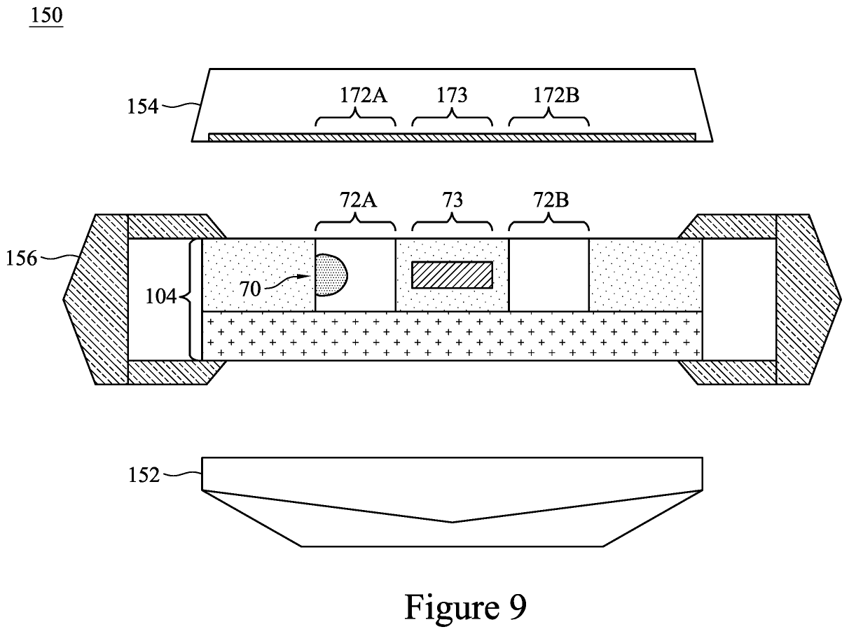

FIG. 9 illustrates a transmission inspection system 150, in accordance with some embodiments. The transmission inspection system 150 shown in FIG. 9 is intended as a simplified schematic illustration for explanatory purposes, and accordingly some details, features, or components may not be shown. The transmission inspection system 150 comprises an emitter 152 and a detector 154, which may be similar to those described previously. The emitter 152 is configured to emit light toward the detector 152. In some embodiments, a handler 156 holds a semiconductor structure 104 between the emitter 152 and the detector 154. The handler 156 may comprise robotic arms, a clamp, a platter, a ring, or the like that does not fully cover one or both sides of the semiconductor structure 104. In some embodiments, the handler 156 may be a transfer robot or the like. The handler 156 may be configured to adjust the position of the semiconductor structure 104, and may be communicatively coupled to the controller 106, in some embodiments.

In some embodiments, the semiconductor structure 104 may comprise one or more transmittable regions 72 and one or more opaque regions 73. As an example, FIG. 9 illustrates a semiconductor structure 104 having a transmittable region 72A and a transmittable region 72B, and an example opaque region 73. Other numbers or configurations of transmittable regions 72 or opaque regions 73 are possible. Further, the transmittable region 72A is shown having a defect 70, which may be similar to a defect 70 described previously, in some cases. As shown in FIG. 9, the detector 154 has a detection region 172A corresponding to the transmittable region 57A, a detection region 172B corresponding to the transmittable region 72B, and a detection region 173 corresponding to the opaque region 73. In other embodiments, a detector 154 may have more or fewer detection regions, may have detection regions of other sizes, or may have a single continuous detection region.

The handler 156 may be configured to position the semiconductor structure 104 such that at least one transmittable region 72 is uncovered, and may be configured to position the semiconductor structure 104 such that light emitted from the emitter 152 may travel through at least one transmittable region 72 and be detected by the detector 154. In some embodiments, the handler 156 may position the semiconductor structure 104 such that the semiconductor structure 104 is vertically separated from the emitter 152 and the detector 154, as shown in FIG. 9. In other embodiments, the emitter 152 and/or the detector 154 may make physical contact with the semiconductor structure 104. Other arrangements, configurations, or orientations of the emitter 152, the detector 154, and/or the semiconductor structure 104 are possible.

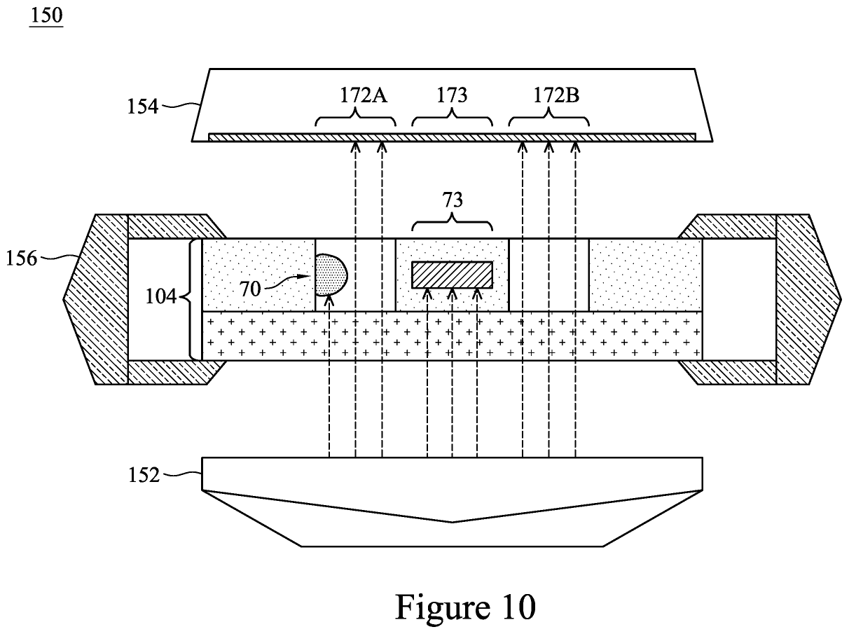

FIG. 10 illustrates a schematic illustration of a transmission inspection system 150 during an inspection process, in accordance with some embodiments. During the inspection process, the emitter 152 emits light toward the semiconductor structure 104 and light that is transmitted through the semiconductor structure 104 may be detected by the detector 154. In FIG. 10, the light is represented schematically by dashed arrows. The dashed arrows may represent light emitted simultaneously in a single inspection step or light emitted sequentially using several inspection steps. In some embodiments, the emitter 152 may emit light such that most or all of a first side of the semiconductor structure 104 is illuminated. In other embodiments, the emitter 152 may emit light such that a portion of the first side of the semiconductor structure 104. For example, the emitter 152 may emit light that only illuminates one or more selected regions 302, in some embodiments. The detector 154 may detect light from most or all of a second side of the semiconductor structure 104 or may detect light from a portion of the second side of the semiconductor structure 104. In some embodiments, the handler 152 may be configured to reposition the semiconductor device 104 to align a specific portion, region 302, and/or transmittable region 72 with the emitter 152 and/or the detector 154. In some embodiments, the emitter 152 and/or the detector 154 may be repositioned to align to a specific portion, region 302, and/or transmittable region 72. In this manner, a single inspection step may be performed on a semiconductor structure 104, or multiple inspection steps may be performed on a semiconductor structure 104.

As shown schematically in FIG. 10, the light emitted from the emitter 152 may be transmitted through the semiconductor structure 104 or may be blocked/absorbed within the semiconductor structure 104. For example, light directed at the opaque region 73 is blocked or absorbed within the opaque region 73, and thus no light is received or detected at the detection region 173 of the detector 154. Some or all of the light directed at the transmittable regions 72A-B may be transmitted through the transmittable regions 72A-B and thus may be received or detected at the detection regions 172A-B. In some cases, the light received at the detector 154 may still be partially absorbed, attenuated, or refracted within a transmittable region 72.

In some cases, a defect may be present in a transmittable region, such as the defect 70 in the transmittable region 72A in FIG. 10. The defect 70 may absorb or block the light from the emitter 152, as shown in FIG. 10. In this manner, the light received at the detector 154 corresponding to the transmittable region 72A may be less than the received light that would be expected if the defect 70 were not present. In this manner, the difference between the light received at a detector 154 and the light expected to be received at the detector 154 may indicate the presence of a defect.

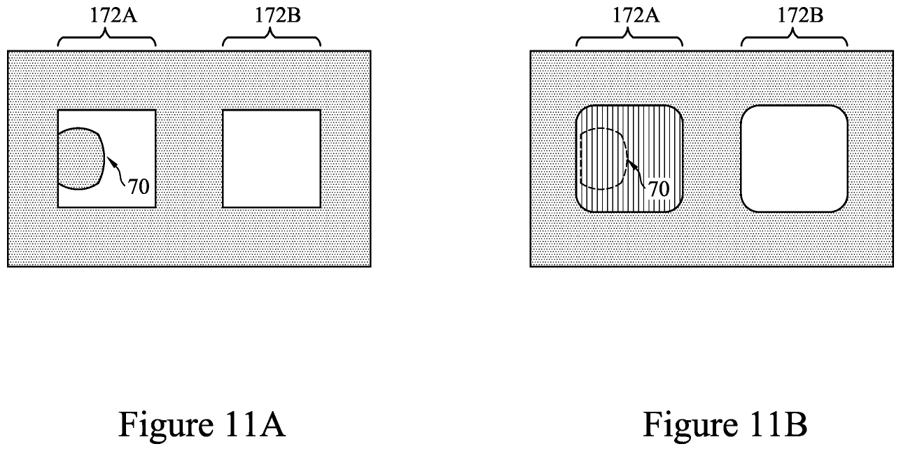

As illustrative examples, FIGS. 11A and 11B each show detected light measurements that correspond to the semiconductor structure 104 of FIG. 10. For example, a detection region 172A and a detection region 172B are shown, which correspond to light received from the transmittable region 72A and the transmittable region 72B, respectively. The measurements shown in FIGS. 11A-11B are intended as explanatory illustrations, and a transmission inspection system 150 may generate detected light measurements or detection data in other forms or using other techniques. The detected light measurements may be generated by the detector 154, or may be transmitted to the controller 106 and generated by the controller 106. In FIGS. 11A-11B, darker regions correspond to lower light intensity detected by the detector 154, and brighter regions correspond to higher light intensity detected by the detector 154. FIG. 11A illustrates a representative measurement from a detector 154 having a relatively high resolution, and FIG. 11B illustrates a representative measurement from a detector 154 having a relatively low resolution or that has been processed. The measurements shown in FIGS. 11A-11B are examples, and other measurements may have different characteristics, which may depend on the characteristics of the transmission inspection system 150 and/or any processing that is performed on the measurements. In some cases, the measurements may not be presented visually by the transmission inspection system 150 like the measurements shown in FIGS. 11A-11B.

In the example of FIG. 11A, the detector 154 has a relatively high resolution, and thus the detected light measurement may show some detail of features or structures, in some cases. In this manner, the detected light measurement may be an image or may be similar to an image, in some cases. As shown in FIG. 11A, the transmittable region 72B is free of defects and thus a relatively high intensity of light is transmitted through the transmittable region 72 and received at the detection region 172B of the detector 72, as indicated by the white square. The transmittable region 72A has a defect 70 that absorbs light, and thus a corresponding portion of the detection region 172A receives a relatively low intensity of light. In some cases, the transmission inspection system 150 described herein can detect, identify, or image defects having a cross-sectional area as small as about 1 μm by 1 μm, but other sizes of detectable defects are possible. In some embodiments, a detected light measurement or a detected image from the detection region 172A may be compared with an expected light measurement or an expected image of the detection region 172A to detect or identify the presence of the defect 70A. For example, in some embodiments, a detected image may be compared pixel-by-pixel (or the like) with an expected image. As an example, the expected light measurement or expected image of the detection region 172A may be a bright region, which may be similar to the detection region 172B, in some cases.

In the example of FIG. 11B, the detector 154 may have a relatively small resolution and/or the detected light measurement may be processed, in some cases. In this manner, finer features or structures, such as a defect 70, may be less defined within the detected light measurement, in some cases. For example, the detector 154 may measure the overall or accumulated light intensity over an area that includes a transmittable region 72 or a portion thereof, in some embodiments. For example, the detection region 172A may correspond to an area of the semiconductor structure 104 that includes the transmittable region 72A. In other embodiments, the measured light intensity over an area may be processed, wherein the area includes a transmittable region 72 or a portion thereof. In some cases, the measured light intensity over an area may be processed to generate one or more values that indicate the measured light intensity. For example, a value corresponding to an area may include the average, median, sum, maximum, minimum, or the like of the measured light intensity of that area. Other techniques are possible.

As shown in FIG. 11B, the transmittable region 72B is free of defects and thus a relatively high intensity of light is transmitted through the transmittable region 72 and received at the detection region 172B of the detector 72, as indicated by the bright region corresponding to the detection region 172B. The transmittable region 72A has a defect 70 that absorbs light, which lowers the overall intensity of light received at the detection region 172A. The relatively lower light intensity is represented by the darker region corresponding to the detection region 172A. The exact location and size of the defect 70 is indicated in FIG. 11B, but the exact location and/or size of a defect 70 may or may not be determinable in a detected light measurement. Comparing the measured light intensity with an expected light intensity may indicate the presence of a defect 70. For example, in some embodiments, a value indicating the light intensity for an area of the semiconductor structure 104 may be below some threshold value that is associated with that area, which can indicate the presence of a defect 70 in that area. In some cases, the transmission inspection system 150 described herein can detect or identify defects in regions having a cross-sectional area as small as about 1 μm by 1 μm, even if the defect itself has a dimension smaller than about 1 μm. It is possible that defects may be detected or identified in regions having a larger or smaller area than this. By measuring the light intensity of an area in this manner, a larger region of a semiconductor structure 104 may be inspected for defects using the transmission inspection system 150, which can reduce inspection time and identify the presence of defects more efficiently, in some cases.

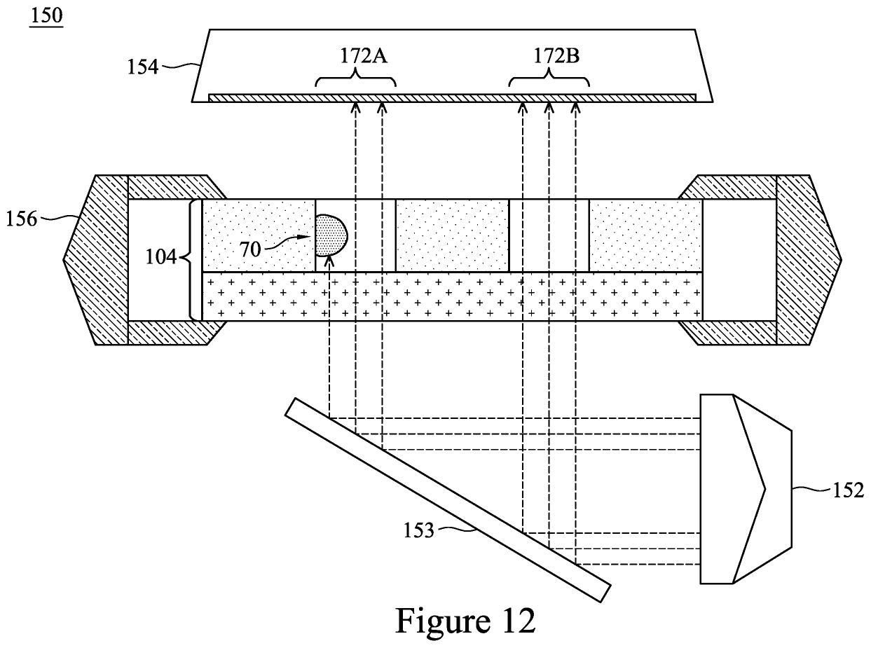

FIG. 12 illustrates a transmission inspection system 150 including a reflector 153, in accordance with some embodiments. The transmission inspection system 150 of FIG. 12 is similar to the transmission inspection system 150 of FIG. 10, except that a reflector 153 redirects the emission (e.g., the light) from the emitter 152 toward the semiconductor structure 104. The reflector 153 reflects or otherwise redirects the light from the emitter 152 toward the semiconductor structure 104 and/or toward a specific region (e.g. region 302) of the semiconductor structure 104. For example, as shown in FIG. 12, the emitter 152 may direct light horizontally or laterally, and the reflector 153 may reflect the light vertically toward the semiconductor structure 104. The reflector 153 may reflect the light at any suitable angle. Other configurations or arrangements are possible. In some embodiments, the reflector 153 may be coupled to actuators that adjust the position and/or angle of the reflector 153. The reflector 153 may comprise a mirror (e.g., planar or curved), a lens, a prism, a grating, optical fibers, the like, or a combination thereof. In some embodiments in which the emitter 152 emits electrons, the reflector 153 may redirect the electrons using appropriate techniques. In some cases, the use of a reflector 153 may decrease the overall dimensions of the transmission inspection system 150 or may allow for improved modularity to the transmission inspection system 150. Additional optical manipulation of the light may be provided by the reflector 153 and allow for improved or more efficient illumination of the semiconductor substrate 104.

FIG. 13 illustrates a transmission inspection system 150 including a stage 160, in accordance with some embodiments. The transmission inspection system 150 of FIG. 13 is similar to the transmission inspection system 150 of FIG. 10, except that the emitter 152 is incorporated into a stage 160 that holds the semiconductor structure 104. The stage 160 may comprise actuators (not shown) that allow the position and/or angle of the stage 160 to be adjusted. In some embodiments, the position/angle of the stage 160 may be controlled by the controller 106. In some embodiments, the position of the stage 160 and the position of the detector 154 may be controlled independently. The emitter 152 is disposed at or near the top of the stage 160 in order to allow the emitted light to be transmitted through the semiconductor structure 104 toward the detector 154. The emitter 152 may be a single emission source or may comprise a plurality of emission sources. In some embodiments, the semiconductor structure 104 may physically contact the emitter 152. In other embodiments, a transparent layer (not shown) may be disposed between the emitter 152 and the semiconductor structure 104. In some embodiments, the transparent layer may comprise a lens or the like. In some cases, incorporating the emitter 152 into the stage 160 can allow for more efficient emission of light into the semiconductor structure 104. In other embodiments, the detector 154 may be placed in physical contact with the semiconductor structure 104, which can improve the detection of transmitted light.

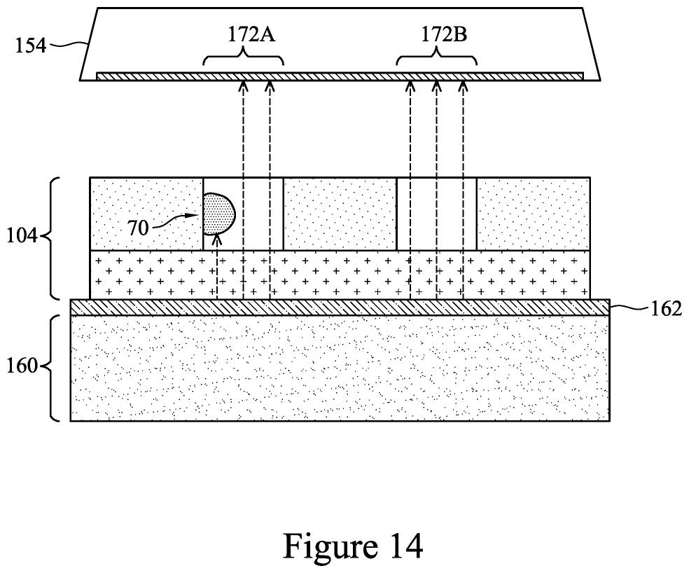

FIG. 14 illustrates a transmission inspection system 150 including a stage 160, in accordance with some embodiments. The transmission inspection system 150 of FIG. 14 is similar to the transmission inspection system 150 of FIG. 13, except that the source of emission is a luminescent layer 162 disposed between the stage 60 and the semiconductor structure 104. The luminescent layer 162 emits light that may be transmitted through the semiconductor structure 104 toward the detector 154. In some embodiments, the luminescent layer 162 may be a liquid layer or a solid layer, and may luminesce using chemiluminescence, phosphorescence, fluorescence, or the like. For example, in some embodiments, the luminescent layer 162 comprises a chemiluminescent liquid that is applied to surfaces of the stage 160 before placing the semiconductor structure 104 on the stage 160. The chemiluminescent liquid may be, for example, a mixture of peroxides, esters, fluorescent dyes, or the like. In other embodiments, the luminescent layer 162 may comprise a layer of a photoluminescent material (e.g., a phosphorescent material, fluorescent material, or the like) that emits light after being excited by a source of energy. The photoluminescent material may be, for example, alkaline earth aluminate, yttrium oxide, or the like. The source of energy may be, for example, another source of light, which may be external to the stage 160 or incorporated within the stage 160. For example, in some embodiments, the stage 160 may include a UV light source that illuminates the luminescent layer 162 and causes the luminescent layer 162 to emit light by a photoluminescence process. This is an example, and other configurations or energy sources are possible. In some embodiments, a transparent layer (not shown) may be disposed between the luminescent layer 162 and the semiconductor structure 104.

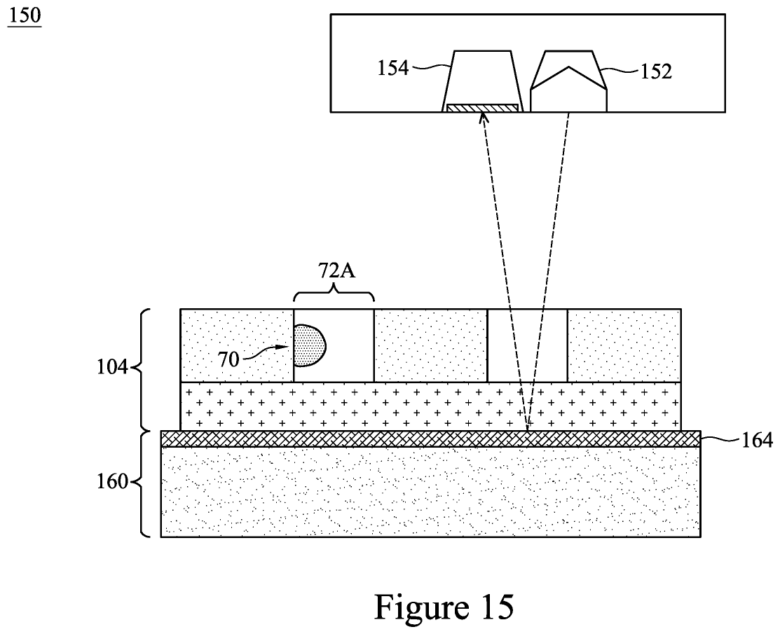

FIG. 15 illustrates a transmission inspection system 150 including a stage 160, in accordance with some embodiments. The transmission inspection system 150 of FIG. 15 is similar to the transmission inspection system 150 of FIG. 13, except that both the emitter 152 and the detector 154 are on the same side of the semiconductor structure 104. For example, the emitter 152 and the detector 154 may be opposite the stage 160, as shown in FIG. 15. In some embodiments, the light emitted from the emitter 152 is transmitted through the semiconductor structure 104 (e.g., through a transmittable region 72), is reflected off of the stage 160, and is transmitted back through the semiconductor structure 104 to be received by the detector 154. In this manner, the emitted light is effectively transmitted twice through the same transmittable region 72 of the semiconductor structure 104. Accordingly, any defects 70 may absorb both emitted light and reflected light, which can increase the sensitivity of the transmission inspection system 150 to the presence of defects 70. In some embodiments, to facilitate reflection of the light at the stage 160, the stage 160 may comprise a reflective layer 164 at or near a top surface of the stage 160.

In some embodiments, the emitter 152 and the detector 154 may be laterally separated, as shown in FIG. 15. Accordingly, the light from the emitter 152 may be directed toward the semiconductor structure 104 at an oblique angle and reflected back at a similarly oblique angle. In other embodiments, the emitted light and the reflected light are perpendicular or approximately perpendicular with respect to the semiconductor device 104. In other words, the emitted light and the reflected light may overlap or be colinear. In some embodiments, the emitter 152 and the detector 154 may be adjacent and a long enough distance from the semiconductor device 104 that the emitted and reflected light are nearly perpendicular with respect to the semiconductor device 104. In some embodiments in which the emitted light and the reflected light are perpendicular with respect to the semiconductor structure 104 (e.g., are colinear), suitable optical components such as a prism, a beam splitter, a partially-reflective mirror, or the like may be used to partially reflect emitted light from the emitter 152 toward the semiconductor structure 104 and/or partially reflect received light from the semiconductor structure 104 toward the detector 154. FIG. 15 shows the emitter 152 and the detector 154 as laterally adjacent, but the emitter 152 and the detector 154 may be laterally separated and/or may be different distances from the semiconductor structure 104, in other embodiments. This is an example, and other arrangements or configurations are possible.

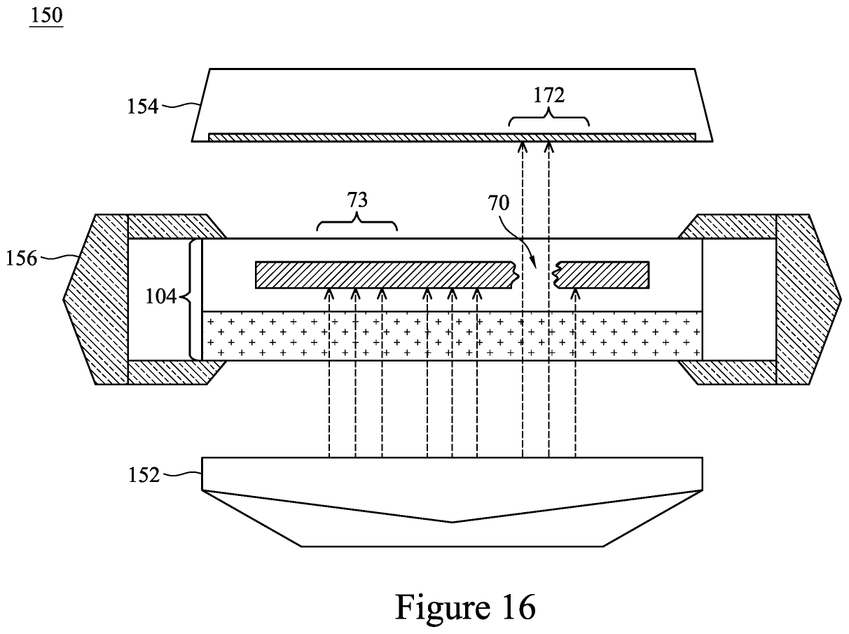

In some embodiments, the transmission inspection system 150 described herein may be used to identify or detect defects comprising the presence of missing material instead of defects comprising the presence of unwanted material as described above. This is illustrated in FIG. 16, which shows a transmission inspection system 150 similar to that shown in FIG. 9. In FIG. 16, a feature present in the semiconductor structure 104 is expected to block or absorb light emitted from the emitter 152. An opaque region 73 is indicated as an example region in which emitted light is blocked/absorbed. However, in some cases, a defect 70 may be formed when material is undesirably removed during processing due to, for example, overetching or the like. In some cases, this missing material defect 70 allows light to be transmitted fully through the semiconductor structure 140. In such cases, the transmission inspection system 150 may be able to identify or detect a missing material defect 70 by detecting transmitted light that is received from unexpected regions of the semiconductor structure 104. The ability of the transmission inspection system 150 to detect missing material defects in this manner may depend on the materials, layout, and/or features of the semiconductor structure 104. This is an example, and other configurations or techniques are possible.

Embodiments may provide advantages. A defect inspection tool comprising a transmission inspection system uses the transmission of light through a semiconductor structure in order to inspect the semiconductor structure for defects. In some cases, the techniques described herein allow for the detection of defects that may be difficult or impossible for other defect inspection techniques, such as bright field or dark field inspection, to detect. For example, the techniques described herein allow for defects within a semiconductor structure or within a cavity to be detected. The techniques described herein may be used to inspect a wide variety of semiconductor structures such as chips, packages, interposers, interconnect structures, or the like. The techniques described herein may be used to detect defects in small areas or over large areas, and may be used to image defects, in some cases. Additionally, the techniques described herein may be used to inspect a semiconductor structure during processing, which can allow for improved processing efficiency and improved yield.

In accordance with an embodiment of the present disclosure, a method includes directing light at a first side of a semiconductor structure; detecting a first light intensity at a second side of the semiconductor structure, wherein the first light intensity corresponds to the light that penetrated the semiconductor structure from the first side to the second side; and comparing the first light intensity to a second light intensity, wherein the second light intensity corresponds to an expected intensity of light. In an embodiment, the method includes determining the presence of a defect based on the comparing of the first light intensity to the second light intensity. In an embodiment, the defect is a residue. In an embodiment, the light is directed at a first region of the semiconductor structure, wherein the first region extends from the first side of the semiconductor structure to the second side of the semiconductor structure. In an embodiment, the second light intensity is associated with the first region. In an embodiment, directing light at the first side of the semiconductor structure includes emitting light from a light source and using a reflector to reflect the light toward the first side. In an embodiment, the light is visible light.

In accordance with an embodiment of the present disclosure, a method includes patterning a first region of a semiconductor structure, wherein the semiconductor structure has a first side and a second side; positioning the semiconductor structure between a light source and a light detector; using the light source, illuminating the first side of the semiconductor structure with light, wherein the light enters the first region; using the light detector, detecting light from the second side of the semiconductor structure to generate a first light measurement; and based on the first light measurement, determining if a defect is present in the first region. In an embodiment, patterning the first region includes etching a trench in the first region. In an embodiment, the light source is a laser light source. In an embodiment, the light source is a chemiluminescent light source. In an embodiment, determining if a defect is present in the first region includes comparing a first value of the first light measurement to a second value of a second light measurement. In an embodiment, the second light measurement is generated before the first light measurement. In an embodiment, generating the first light measurement includes averaging multiple light intensity measurements. In an embodiment, positioning the semiconductor structure includes placing the semiconductor on a stage, wherein the light source is in the stage. In an embodiment, the positioning the semiconductor structure includes holding the semiconductor structure in a location that is vertically separated from the light source and the light detector.

In accordance with an embodiment of the present disclosure, a defect inspection system includes a light emitter; a light detector configured to detect light emitted from the light emitter and generate detection data based on the detected light; a holder configured to hold a semiconductor structure between the light emitter and the light detector; and a controller configured to receive the detection data from the light detector and analyze the detection data to determine whether the workpiece has a defect. In an embodiment, the holder is a stage. In an embodiment, the stage includes the light emitter. In an embodiment, the light detector is a CCD device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
directing light at a first side of a semiconductor structure;
detecting a first light intensity at a second side of the semiconductor structure, wherein the first light intensity corresponds to the light that penetrated the semiconductor structure from the first side to the second side; and
comparing the first light intensity to a second light intensity, wherein the second light intensity corresponds to an expected intensity of light.

2. The method of claim 1 further comprising determining the presence of a defect based on the comparing of the first light intensity to the second light intensity.

3. The method of claim 2, wherein the defect comprises a residue.

4. The method of claim 1, wherein the light is directed at a first region of a plurality of regions of the semiconductor structure, wherein the first region extends from the first side of the semiconductor structure to the second side of the semiconductor structure.

5. The method of claim 4, wherein the second light intensity is associated with the first region.

6. The method of claim 1, wherein directing light at the first side of the semiconductor structure comprises:
emitting light from a light source; and
using a reflector to reflect the light toward the first side.

7. The method of claim 1, wherein the light is visible light.

8. A method comprising:
patterning a first region of a semiconductor structure, wherein the semiconductor structure has a first side and a second side;
positioning the semiconductor structure between a light source and a light detector;
using the light source, illuminating the first side of the semiconductor structure with light, wherein the light enters the first region;
using the light detector, detecting light from the second side of the semiconductor structure to generate a first light measurement; and
based on the first light measurement, determining if a defect is present in the first region.

9. The method of claim 8, wherein patterning the first region comprises etching a trench in the first region.

10. The method of claim 8, wherein the light source is a laser light source.

11. The method of claim 8, wherein the light source is a chemiluminescent light source.

12. The method of claim 8, wherein determining if a defect is present in the first region comprises comparing a first value of the first light measurement to a second value of a second light measurement.

13. The method of claim 12, wherein the second light measurement is generated before the first light measurement.

14. The method of claim 8, wherein generating the first light measurement comprises averaging a plurality of light intensity measurements.

15. The method of claim 8, wherein positioning the semiconductor structure comprises placing the semiconductor on a stage, wherein the light source is in the stage.

16. The method of claim 8, wherein the positioning the semiconductor structure comprises holding the semiconductor structure in a location that is vertically separated from the light source and the light detector.

17. A defect inspection system comprising:
a light emitter;
a light detector configured to detect light emitted from the light emitter and generate detection data based on the detected light;
a holder configured to hold a semiconductor structure between the light emitter and the light detector; and
a controller configured to receive the detection data from the light detector and analyze the detection data to determine whether the workpiece has a defect.

18. The defect inspection system of claim 17, wherein the holder is a stage.

19. The defect inspection system of claim 18, wherein the stage comprises the light emitter.

20. The defect inspection system of claim 17, wherein the light detector is a CCD device.
